(19) United States
(12) Patent Application Publication
(10) Pub. No.: US 2025/0038037 A1
(43) Pub. Date: Jan. 30, 2025

(54) WAFER LAMINATION SYSTEMS AND METHODS THEREOF FOR SEMICONDUCTOR WAFERS

(71) Applicant: UTAC Headquarters Pte. Ltd., Singapore (SG)

(72) Inventors: IL KWON SHIM, Singapore (SG); Dzafir Bin Mohd Shariff, Singapore (SG); Ronnie M. De Villa, Singapore (SG); Enrique E. SARILE, JR., Singapore (SG); Chee Kay Chow, Singapore (SG); Jackson Fernandez Rosario, Singapore (SG); Chan Loong Neo, Singapore (SG)

(21) Appl. No.: 18/393,621

(22) Filed: Dec. 21, 2023

Related U.S. Application Data
(60) Provisional application No. 63/434,458, filed on Dec. 21, 2022.

(51) Int. Cl. H01L 21/683; H01L 21/67; H01L 21/687

(52) U.S. Cl. CPC H01L 21/6836; H01L 21/67132; H01L 21/67144; H01L 21/68707; H01L 2221/68327; H01L 2221/68386

(57) ABSTRACT

Lamination systems and methods of fabricating devices are disclosed. The lamination system includes multiple processing modules for delaminating a backgrinding (BG) from a surface of the wafer and laminating a dicing tape on the surface of the wafer. The system includes a wafer receiving module which is configured to hold the wafer in place with a position chuck throughout the delamination and lamination process. By using a single positioning chuck, more efficient processing is achieved. For example, there is no need to re-lign the wafer when it is moved from one chuck to another.

### CROSS-REFERENCE TO RELATED APPLICATION

This application claims the benefit of U.S. Provisional Application No. 63/434,458, filed on Dec. 21, 2022, which is incorporated herein by reference in its entirety for all purposes.

### FIELD OF THE INVENTION

The present disclosure relates to semiconductor devices and methods thereof. In particular, the present disclosure relates to wafer lamination systems and methods thereof for processing semiconductor wafers.

### BACKGROUND

In semiconductor processing, devices are formed in parallel on a wafer. A singulation process is performed to separate the wafer into individual devices. Typically, a mechanical saw is employed to separate the wafer into individual dies. To increase performance, high-k dielectric materials are used in the formation of interconnects as part of the back end (BE) dielectric stack. However, the high-k BE dielectric stack is prone to damage due to the vibration of mechanical sawing

To avoid damaging the high-k BE dielectric, plasma dicing is employed instead of mechanical sawing to singulate the wafer. Plasma dicing includes laminating a wafer on a dicing tape attached to a wafer ring. The wafer ring with the wafer (wafer ring assembly) is positioned in a plasma dicing chamber to singulate the wafer.

To laminate a wafer for plasma dicing, two separate pieces of equipment or tools are needed. For example, to expedite the plasma dicing process, the wafer is thinned by back grinding (BG) the back (inactive) side of the wafer to reduce plasma dicing time. This means that one tool is needed to remove the BG tape and one tool is needed to laminate the dicing tape onto the wafer. Two separate tools make the plasma dicing of wafers more complex and time-consuming, increasing the overall production cost. In addition, two separate tools require more space, further adding to the overall production cost.

From the foregoing discussion, there is a desire to provide a cost-effective way to laminate wafers for plasma dicing.

### SUMMARY

Embodiments generally relate to lamination systems and methods for fabricating devices.

One embodiment relates to a lamination system for manufacturing semiconductor devices. The system includes an input sub-system, a processing sub-system and an output sub-system.

The input sub-system is configured with a robotic arm of a robotic module for picking up a wafer. The wafer includes first and second wafer surfaces. A backgrinding (BG) tape is attached to the first wafer surface. For example, the second wafer surface is a ground surface. The wafer may be thinned by grinding the second wafer surface until a desired thickness is reached. A wafer aligner module aligns the wafer on the robotic arm. In one embodiment, the robotic arm attaches to the BG tape on the wafer. For example, an end effector of the robotic arm attaches to the BG tape on the first wafer surface. The aligned wafer on the robotic arm is transferred to the processing sub-system.

The processing sub-system includes a wafer receiving module (WRM) and various processing modules configured to perform delamination of the BG tape from the first wafer surface and laminating a dicing tape after the BG has been delaminated. The dicing tape laminates the wafer to a wafer ring to form a wafer ring assembly. The WRM includes a positioning chuck. The robotic arm is configured to place the wafer aligned on thereon onto the positioning chuck. A second surface of the wafer is attached to and held into position by the position chuck, leaving the BG tape exposed. The WRM transfers the wafer to the various modules for processing to form the wafer ring assembly.

As for the output sub-system, it includes an output module for an output module. The output module is configured to pick up the wafer ring assembly from the WRM and outputs it from the lamination system. The wafer ring assembly may be further processed to dice the wafer thereon, separating it into individual dies or devices.

Another embodiment relates to a method of fabricating devices. The method includes providing a wafer having first and second major surfaces. The first major surface includes a backgrinding tape (BG) tape laminated thereto. A robotic module picks up the wafer and is aligned by a wafer aligner module. The robotic module transfers the aligned wafer to a wafer receiving module (WRM). The robotic module places the wafer on a positioning chuck of the WRM. The second major surface of the wafer is held by the positioning chuck.

The WRM transfers the wafer to various processing modules of a processing sub-system to delaminate the BG tape from the first wafer surface and to laminate a dicing tape on the first wafer surface. The dicing tape is laminated to a wafer ring to form a wafer ring assembly. The wafer ring assembly is transferred to the output module by the WRM. The output module outputs the wafer ring assembly for subsequent processing, including wafer singulation to separate the wafer into individual devices.

These and other advantages and features of the embodiments herein disclosed will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of various embodiments. In the following description, various embodiments of the present disclosure are described with reference to the following, in which:

FIG. 1a shows a simplified top view of a processed wafer;

FIG. 1b shows a simplified view illustrating the layout of an embodiment of a wafer lamination system;

FIG. 1c shows a dicing tape roll with appropriately sized precut dicing tapes;

FIG. 2 shows a simplified isometric view of an embodiment of a wafer receiving module (WRM);

FIG. 3 shows a simplified isometric view of an embodiment of a WRM track for moving the WRM within the lamination system;

FIG. 4 shows a simplified view of the wafer ring pick and place module;

FIGS. 5a-5c show simplified top views of an embodiment of an output module in operation;

FIG. 6a shows an embodiment of a 6-axis robotic module;

FIG. 6b shows a simplified view of an embodiment of an end effector of the robotic module; and

FIG. 7 shows an embodiment of a process flow for laminating a wafer.

### DETAILED DESCRIPTION

Embodiments described herein generally relate to semiconductor processing for producing devices. The embodiments, in particular, relate to cost-effectively laminating wafers for plasma dicing to form devices.

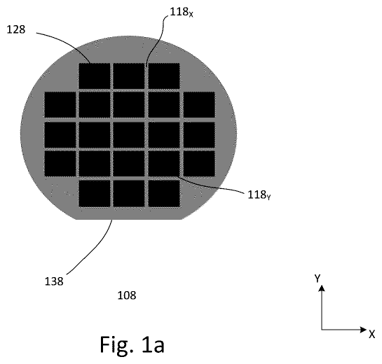

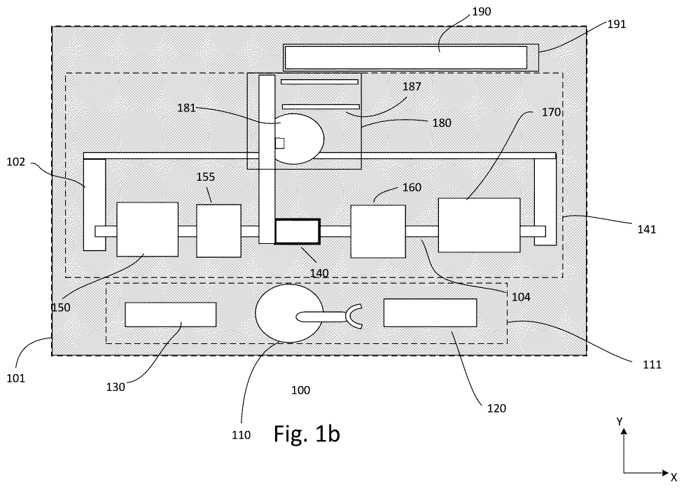

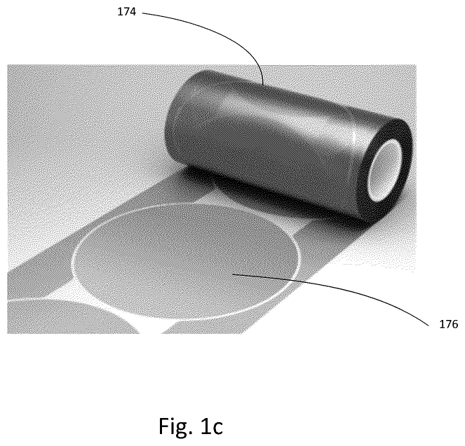

FIG. 1a shows a simplified top view of a processed wafer 108. The wafer, for example, is a semiconductor wafer, such as a silicon wafer. Other types of wafers may also be useful. The wafer includes first and second opposing major surfaces. The first surface, for example, may be an active surface on which devices 128 are formed. The second surface, for example, may be an inactive surface. The devices are separated by orthogonal saw streets or dicing channels 118_{X} and 118_{Y} in the x and y directions. The wafer may include a notch 138 for alignment purposes. To singulate the wafer, it is diced along the orthogonal saw streets, resulting in individual devices.

Referring to FIG. 1b, a simplified top view of an embodiment of a wafer lamination system 100 is shown. The simplified top view illustrates a layout of the lamination system to cost-effectively laminate the wafer for plasma dicing with a reduced or minimal footprint. The lamination system is an integrated system which delaminates the back grinding (BG) tape from an incoming wafer and laminates it with a dicing tape.

As shown, the lamination system includes an input sub-system 111, a processing sub-system 141 and an output sub-system 191. The different sub-systems are mounted on a rectangular-shaped system platform or body 101. Other shaped system platforms may also be useful. In one embodiment, the input sub-system and the output sub-system are disposed on opposing sides of the processing sub-system along the y-direction. For example, incoming wafers are provided at the input sub-system, processed by the processing sub-system and output by the output sub-system. Other configurations of the sub-systems which efficiently process the incoming wafers with minimal system footprint may also be useful.

In one embodiment, the input sub-system includes a robotic module 110, a wafer input module 120 and a wafer aligner module 130. The processing sub-system includes a wafer receiving module (WRM) 140 and a WRM track 104 for moving the WRM within the lamination system. On the first opposing side of the WRM along the x direction is disposed a back grinding (BG) tape delamination module 150; on a second opposing side of the WRM along the x direction is disposed a dicing tape lamination module 170. A wafer ring pick and place module 180 is disposed proximate to the output sub-system. In one embodiment, the wafer ring pick and place module includes a pick and place arm 181 and a wafer ring track 187. The various processing modules may be supported on the system platform by a system frame 102. The WRM track is disposed on the system body and/or frame to facilitate the movement of the WRM to the different processing modules. As for the output module 190, as already discussed, it is disposed on an opposing side of the processing sub-system as the input sub-system. Other layout configurations may also be useful. The layout should promote efficient processing flow for delamination and lamination of a wafer ring.

As discussed, the input sub-system includes the wafer input module, the robotic module and the wafer aligner module. The input module is configured to receive a cassette of incoming wafers. An incoming wafer includes a BG tape on the front (active) side of the wafer. For example, the back (inactive) wafer side has been thinned to the desired thickness by back grinding and polishing. The input module is configured to feed incoming wafers for the robotic module. The incoming wafers are preferably configured such that the inactive surface is facing upwards. For example, the polished side of the wafer is facing upwards. This avoids the polished surface of the wafer from contacting any other surface to maintain cleanliness after polishing.

The robotic module is configured to pick up an incoming wafer from the input module and transfer it to the wafer aligner module. In one embodiment, the robotic module includes a multi-axis or degrees of freedom robotic arm. The robotic arm includes end effectors for grasping an incoming wafer from the input module using, for example, vacuum pressure. In one embodiment, the end effectors contact the BG tape on the wafer. For example, the end effectors grasp the tape side of the wafer. Other techniques or configurations for grasping the wafer may also be useful.

In one embodiment, prior to transferring it to the aligner module, the robotic module flips the incoming wafer 180° so that the BG tape is facing upwards. The wafer aligner module aligns the wafer on the robotic arm. The robot arm can be configured to rotate and laterally shift x-y directions during the alignment process. In one embodiment, the aligner module aligns the wafer using the wafer notch as a reference for wafer orientation and the edge of the wafer as a reference for alignment and centering. Other alignment techniques or configurations may also be useful. For example, in some embodiments,

After alignment, the robotic module transfers the aligned wafer to the WRM of the processing sub-system for processing. The robotic module, in one embodiment, is disposed on an x-y robot track system to facilitate movement to the input module, the wafer aligner module and the WRM module of the processing sub-system.

Regarding the WRM module, it receives the incoming wafer from the robotic module with the BG tape facing upwards. The WRM module includes a WRM table with a positioning chuck to hold the wafer in position, the polished surface is facing the positioning chuck. For example, the chuck may hold the wafer in position by vacuum pressure. In addition, the WRM may include alignment pins for aligning a wafer ring to the WRM in a subsequent process. Since the aligner module has already aligned the wafer to the robotic arm, the wafer is also aligned to the positioning chuck of the WRM. Once positioned onto the chuck, the wafer remains thereon until processing is completed. This advantageously avoids the need for realignment, simplifying the overall wafer lamination process.

The positioning chuck, for example, holds the wafer in position by vacuum pressure on the polished surface. The positioning chuck may be under the wafer. For example, the positioning chuck is located under the polished side of the wafer. In other embodiments, the positioning chuck can be configured to be on top of the wafer when the BG tape is facing down. This ensures that the polished side of the wafer is attached to the positioning chuck. The wafer can be flipped either before or after alignment. Preferably, flipping of the wafer is performed before alignment to prevent any change in alignment during flipping.

The WRM module proceeds to the delamination module for processing. In one embodiment, the delamination module includes a curing unit 155 and a tape removal unit 150. The curing unit cures the BG tape using UV radiation before it reaches the tape removal unit. The curing reduces the adhesivity of the BG tape, facilitating its removal. In one embodiment, the WRM moves through the curing unit as the BG tape is cured on its way to the tape removal unit. Preferably, sticky assist tape is applied to one edge of the BG tape, the sticky assist tape is pulled to peel the BG tape from the wafer surface. After peeling, the BG tape and the sticky assist tape are disposed of. For example, the peeled BG tape is placed in a disposal bin for peeled BG tapes.

After BG tape removal, the WRM moves to the wafer ring pick and place module. The ring pick and place module includes a pick and place arm which picks up a wafer ring, positions the ring and places it onto the WRM table with the delaminated wafer. The wafer ring is positioned using, for example, position pins on the WRM table. The pick and place module, for example, receives a wafer ring from a wafer ring repository, which places it on a ring track for pick up by the pick and place arm.

WRM with the ring and delaminated wafer proceeds to the lamination module for processing. The lamination module includes a cleaning unit 160 and a tape lamination unit 170. The cleaning module cleans the surface of the wafer. For example, the surface from which the BG tape has been removed is cleaned. In one embodiment, the cleaning module includes an ionizer and air cleaning unit. The cleaning module, for example, employs air and suction force to remove particles from the surface of the wafer. The ionizer is configured to remove static. In one embodiment, the WRM moves through the cleaning unit as it cleans.

The cleaned wafer progresses to the lamination unit. The lamination unit is configured to laminate the dicing tape on the wafer surface. For example, the dicing tape is laminated on the cleaned surface. In one embodiment, the dicing tape is laminated on the same surface from which the BG tape was removed. Since the inactive surface is maintained on the chuck, this minimizes the inactive surface from particle contamination by minimizing its exposure or handline.

The lamination unit includes a tape supply which dispenses the dicing tape from lamination over the wafer and wafer ring. In one embodiment, the dicing tape is sized appropriately to be about the same size or slightly smaller than the wafer ring. This advantageously avoids the need for cutting or trimming the dicing tape. For example, as shown in FIG. 1c, dicing tape roll 174 may be provided with appropriately sized precut tapes 176. The wafer ring and wafer laminated with the dicing tape may be referred to as a wafer ring assembly.

The WRM moves the wafer ring assembly to the output module. As shown, the WRM track goes through the wafer pick and place module to the output module. Other configurations of the output module may also be useful. The output module is configured to output the wafer ring assembly from the lamination system, completing the lamination process.

In one embodiment, the output module includes an output robot for picking up the wafer ring assembly from the WRM. For example, the robot grasps the wafer ring assembly by the edge thereof, upon which the WRM chuck releases the wafer. This enables the wafer ring assembly to be moved by the robot. The robot transfers the wafer ring assembly to, for example, a conveyor which feeds a wafer ring assembly repository. The wafer ring assemblies, for example, a subsequently processed to singulate the wafer into individual devices by plasma dicing.

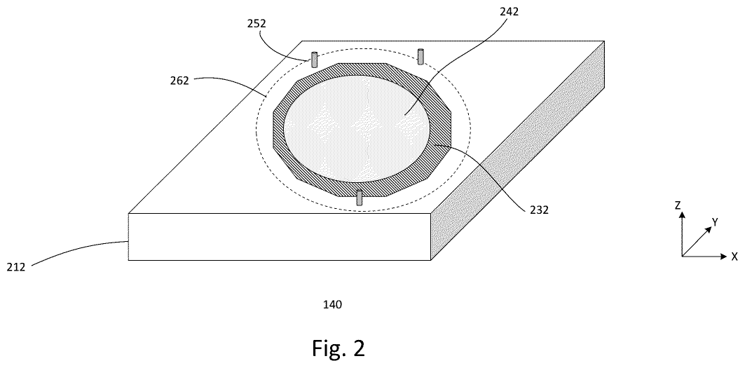

FIG. 2 shows a simplified isotonic view of an embodiment of the WRM 140. The WRM includes a WRM table 212. The WRM table is a translatable table. In one embodiment, the WRM table is translatable in the x and y directions. Preferably, the WRM table is translatable in the X, Y and Z directions. The WRM table includes a positioning chuck assembly. In one embodiment, the positioning chuck assembly is configured to hold an incoming wafer in position. For example, the positioning chuck includes a chuck housing 232 and a chuck 242 disposed therein. The chuck includes a porous surface for vacuum pressure to hold an incoming wafer into position. In one embodiment, the table includes alignment or positioning pins 252 for positioning a wafer ring in a wafer ring region 262.

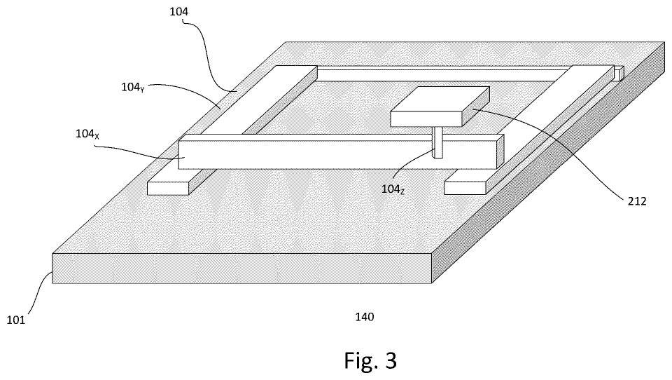

FIG. 3 shows a simplified isometric view of an embodiment of a WRM track 104 for moving the WRM 140 within the lamination system. As shown, the WRM track is configured to move the WRM to the different modules of the lamination system. In one embodiment, the WRM track at least provides X and Y directional translation of the WRM module. For example, the WRM track includes X and Y directional tracks 104_{X} and 104_{Y} for X and Y directional translation within the lamination system. In another embodiment, the WRM track provides X, Y and Z directional translation of the WRM module. For example, the WRM track includes X, Y and Z directional tracks 104_{X}, 104_{Y} and 104_{Z} for X, Y and Z directional translation within the lamination system.

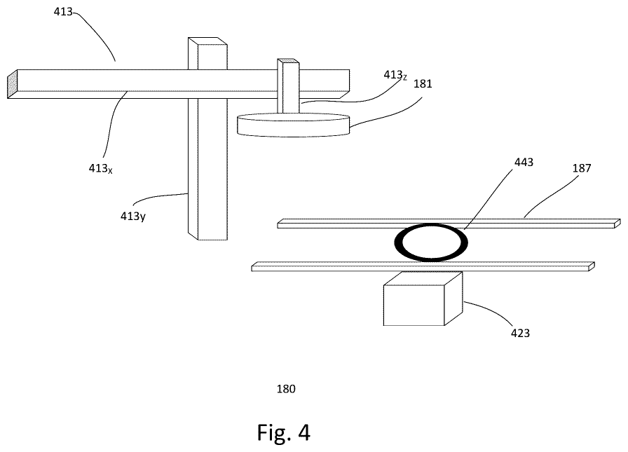

FIG. 4 shows a simplified view of an embodiment of the wafer pick and place module 180. As shown, the wafer pick and place module includes a pick and place gantry or track 413 configured to enable a pick and place arm 181 to translate in the X, Y and Z directions to pick up the wafer ring 443 and align and place it on the WRM with the wafer. In one embodiment, the pick and place module includes a wafer ring track 187 and a wafer ring repository 423 containing a stack or supply of wafer rings. Wafer rings are fed to the track for pickup by the pick and place arm. For example, when ready, the track moves a wafer ring to a pickup position on the track to be picked up by the pickup arm. For example, the pick and place arm is translated to the pickup position, lowered to pick up the wafer ring, raised from the pickup position, translated to the place position and lowered to place the wafer ring onto the WRM table which is positioned by the positioning pins. The WRM with the wafer ring is then moved to the lamination module.

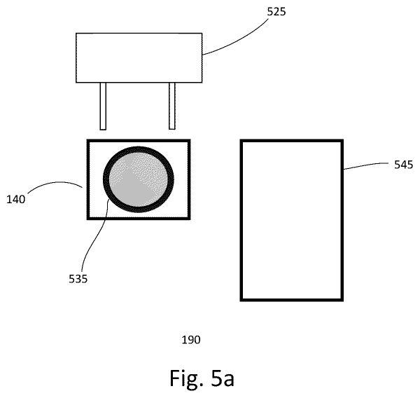

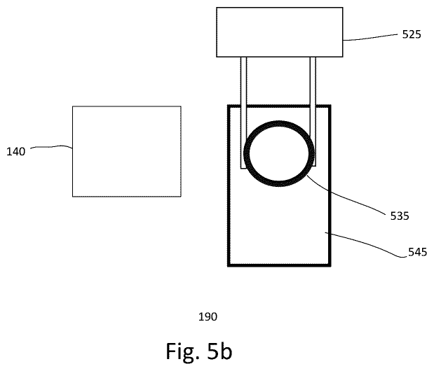

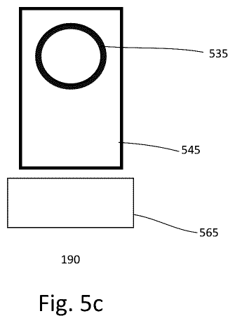

FIGS. 5a-5c show simplified top views of an embodiment of an output module 190 in operation. Referring to FIG. 5a, the output module is shown. In one embodiment, the output module includes an output robot 525 and an output conveyor 545. As shown, a WRM 140 with a wafer assembly 535 arrives at the output module. As shown in FIG. 5b, the robot is configured to remove the wafer ring assembly 535 from the WRM 140. For example, the chuck releases to enable the output robot to pick up the wafer assembly. The output robot moves to the conveyor 545 and loads the wafer assembly thereon. The conveyor 545 moves the wafer ring assembly 535 to a wafer assembly repository 565, as shown in FIG. 5c. The conveyor unloads the wafer ring assembly to a wafer ring assembly repository. When full, the wafer ring assembly repository is transferred to a plasma dicing chamber for dicing the wafers of the wafer ring assemblies in the repository.

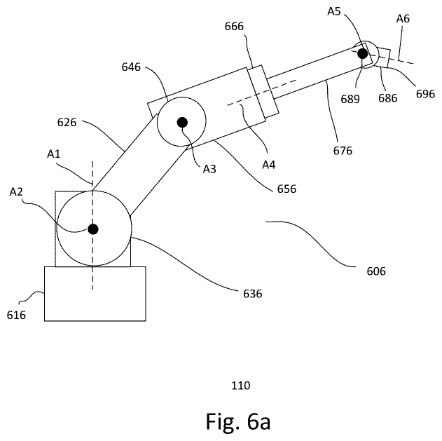

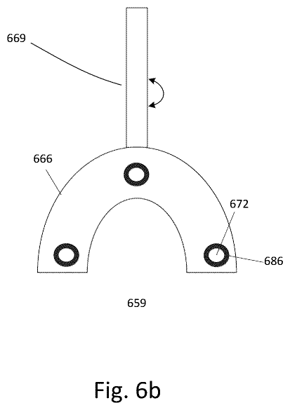

FIG. 6a shows a simplified embodiment of a multi-axis robotic module 110. The robotic module includes a robotic arm 606 mounted on a base 616. As shown, the robotic module is a 6-axis robotic module. Other types of robotic modules, such as a 5-axis robotic module, may also be useful. The base is a rotatable base. In one embodiment, the base is configured to rotate about a first axis of rotation A1. A first arm member 626 of the robotic arm is connected to the base. For example, a shoulder end 636 of the first arm member 626 is connected to the base. The shoulder end enables the first arm member to rotate about a second axis of rotation A2. A first end of a second arm member 656 is coupled to an elbow end 646 of the first arm member. The elbow end enables the second arm member to rotate about a third axis of rotation A3. A second end of the second arm member includes a first wrist joint 666.

In one embodiment, a third arm member 676 is connected to the first wrist joint for rotating it about a fourth axis of rotation A4. An opposing end of the third arm member includes a second wrist joint 689. The second wrist joint is connected to a fourth arm member 686. The wrist joint rotates the fourth arm member about a fifth axis of rotation A5. An end 696 of the arm formed by an end of the fourth arm member is a third wrist joint. In one embodiment, an end effector (not shown) is coupled to the third wrist joint, rotating the end effector about a sixth axis of rotation A6. For example, this enables flipping of the wafer held by the end effector.

The end effector is configured to grasp an incoming wafer from the input module. For example, the robotic arm can be rotated and extended to pick up the incoming wafer from the input module. The robotic arm can then be retracted, rotated and extended to the wafer aligner module for alignment. After alignment, the robotic arm may be retracted, configured to rotate the end effector to flip the wafer and extended to the WRM of the processing sub-system. In some embodiments, the base of the robotic module may be mounted onto an x-y translatable platform to facilitate movement among the modules, such as the input module, wafer aligner module and the WRM.

FIG. 6b shows an embodiment of an end effector 659 of the robotic module. As shown, the end effector includes a wafer grasping end 666. The wafer grasping end, for example, has a semicircular shape which includes vacuum openings 672. A rubber cup 686 lines the vacuum openings, ensuring a vacuum seal to grasp the wafer. An end effector coupling end 669 is connected to the grasping end. The end effector coupling end is configured to couple to the end effector coupler (third wrist) on the robotic arm. The end effector coupler, for example, is a rod-like elongated member coupled to the end effector coupler of the robotic arm. The end effector coupler is rotatable, facilitating the rotation of the end effector to flip the wafer.

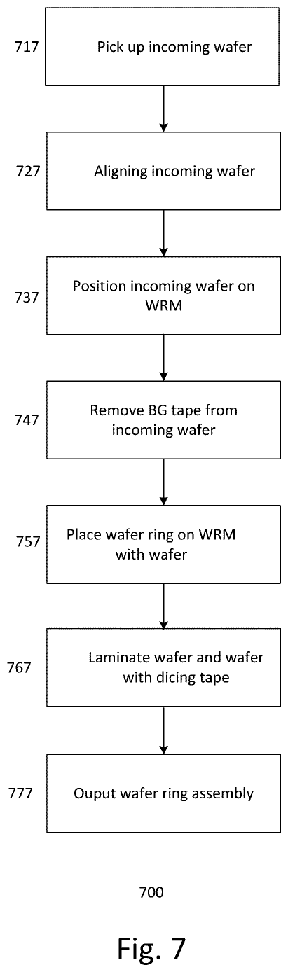

FIG. 7 shows an embodiment of a process flow for laminating a wafer. At 717, the robotic module picks up an incoming wafer for processing from the input module. The incoming wafer, for example, includes a BG tape on an active surface of the processed wafer with dies formed thereon. In one embodiment, the polished side of the wafer is facing upwards when the robotic arm picks it up. For example, an end effector of the robotic arm attaches to the edge of the BG tape side of the wafer using vacuum pressure. The wafer is flipped 180° by rotating the end effector on the robotic arm.

At 727, the incoming wafer on the robotic arm is aligned by the wafer aligner module. For example, the robotic arm with the incoming wafer is moved to the wafer aligner. At the wafer aligner module, a sensor determines the location of the notch on the wafer for alignment. The robot arm adjusts the position of the wafer based on the location of the notch. This is done while the wafer is on the end effector. After the position of the notch is adjusted, the robot arm rotates the wafer 360 degrees. If the notch is misaligned after the rotation, the robot arm adjusts the position of the wafer to center the wafer. The process may be repeated until the wafer is aligned and centered. In one embodiment, the wafer notch is used to orient the wafer and the wafer edge is used for positioning, such as aligning and centering.

The robotic module moves to the processing module at 737. The robotic module moves between the modules via the robotic track. In one embodiment, the robotic module positions the incoming wafer on the chuck of the wafer receiving module (WRM) of the processing sub-system. The BG tape is facing up on the chuck.

The WRM, at 747 transports the wafer to the delamination module for removal of the BG tape. In one embodiment, the BG tape is cured by the curing unit along the way to the tape removal unit. For example, the WRM travels along the WRM track through the curing unit without stopping to cure the BG tape. When the WRM reaches the tape removal unit, it stops for the tape removal unit to remove the BG tape.

After tape removal, the WRM moves to the wafer ring pick and place module at 757. At the wafer ring pick and place module, a pick arm picks a wafer ring from the wafer ring repository and places on the chuck table. Subsequently, the WRM with the wafer and wafer ring moves to the lamination module at 767. In one embodiment, the wafer and wafer ring are cleaned by the cleaning unit. In one embodiment, the WRM moves through the cleaning unit, similar to the curing unit, at stops at the lamination unit. At the lamination unit, a dicing tape is laminated onto the wafer ring and inactive wafer surface, producing a wafer ring assembly.

After lamination, at 777, the WRM moves to the output sub-system. The output module then removes the wafer ring assembly from the WRM. The wafer ring assembly is loaded onto a conveyor of the output module. The conveyor feeds the wafer ring assembly to a wafer ring repository. When the wafer ring repository is full, it is removed. For example, the wafer ring repository is transported for subsequent processing by a plasma dicing chamber to singulate the wafers into individual dies.

As described, efficient and cost-effective dicing tape lamination is achieved using a single tool with a single chuck.

The inventive concept of the present disclosure may be embodied in other specific forms without departing from the spirit or essential characteristics thereof. The foregoing embodiments, therefore, are to be considered in all respects illustrative rather than limiting the invention described herein. The scope of the invention is thus indicated by the appended claims, rather than by the foregoing description, and all changes that come within the meaning and range of equivalency of the claims are intended to be embraced therein.

1. A lamination system for processing wafers comprising:
an input sub-system, the input sub-system is configured with a robotic arm of a robotic module for
picking up a wafer, wherein the wafer includes and a first wafer surface, the first wafer surface includes a first tape attached thereon, and
aligning the wafer;
a processing sub-system, the wafer processing system includes a wafer receiving module (WRM) and various processing modules configured to perform delamination of the first tape from the first wafer surface and laminating a second tape on the first wafer surface after the first tape has been delaminated, wherein the second tape laminates the wafer to a wafer ring to form a wafer ring assembly, wherein
the WRM includes a positioning chuck, the robotic arm is configured to place the wafer aligned on the robotic arm onto the positioning chuck, a second surface of the wafer is attached to and held into position by the positioning chuck, leaving the first tape exposed, and
after attaching the wafer onto the positioning chuck, the WRM transfers the wafer on the positioning chuck to various processing modules for processing while remaining on the positioning chuck; and
an output sub-system, wherein the output sub-system is configured to pick up the wafer ring assembly from the WRM and output it from the lamination system.

2. The system of claim 1 wherein the processing sub-system comprises:
a delamination module, wherein the delamination module is configured to peel a cured first tape from the first wafer surface of the wafer from the WRM;
a wafer ring pick and place module, wherein the wafer ring pick and place module is configured
to pick up a wafer ring from a wafer ring repository,
align the wafer ring to the wafer, and
place the wafer ring onto the WRM with the wafer;
a lamination module, wherein the lamination module is configured to laminate a pre-cut second tape onto the first wafer surface and wafer ring to form the wafer ring assembly; and
wherein the WRM includes
a WRM table with the positioning chuck, the WRM table is configured to hold the wafer ring in place and includes positioning pins for aligning the wafer ring, and
the WRM is centrally disposed within the processing sub-system and moves to various modules of the sub-processing system along a WRM track.

3. The system of claim 2 wherein the delamination module comprises:
a curing unit configured to cure the first tape on the first wafer surface; and
a delamination unit configured to peel the cured first tape from the first wafer surface.

4. The system of claim 2 wherein the lamination module comprises:
a cleaning unit for cleaning the first wafer surface of the wafer after removal of the first tape removal, wherein the wafer is disposed on the positioning chuck along with the wafer ring; and
a lamination unit, the lamination unit laminates the precut second tape on the first wafer surface and the wafer ring.

5. The system of claim 2 wherein the wafer ring pick and place module comprises:
a wafer ring repository containing a wafer ring stack of wafer rings;
a wafer ring track, wherein the wafer ring track is configured to receive wafer rings from the wafer ring repository; and
a wafer ring robotic arm configured to
pick up the wafer ring from the wafer ring track,
align the wafer ring to the wafer, and
placing the wafer ring onto the WRM with the wafer.

6. The system of claim 1 wherein the input sub-system module comprises:
a wafer input module, the wafer input module is configured to hold a wafer cassette of wafers,
a robotic module configured to
pick up the wafer from the wafer cassette, and
flip the wafer 180° so that the first wafer surface with the first tape is facing upwards; and
a wafer aligner module, wherein the robotic arm moves the wafer to the wafer aligner module for alignment by the wafer aligner module, the robotic arm moves the wafer after alignment to the WRM.

7. The system of claim 1 wherein the output sub-system comprises a conveyor unit, the conveyer unit is configured:
to receive the wafer ring assembly;
transfer the wafer ring assembly to a wafer ring assembly repository; and
wherein an output robotic arm picks the wafer ring assembly from the WRM and places it on the conveyor unit.

8. The system of claim 8 wherein the output robotic arm comprises a pick and place robotic arm of a pick and place module of the processing sub-system.

9. The system of claim 1 comprises:
a system platform for accommodating the input sub-system, the processing sub-system and the output sub-system;
a WRM track enabling the WRM to move to the various processing modules of the processing sub-system, including receiving the wafer by the WRM from the input sub-system and providing the wafer ring assembly by the WRM for outputting to the output system.

10. The system of claim 10 wherein:
the processing sub-system is centrally disposed on the system platform;
the input sub-system is disposed on a first side of the processing sub-system;
the output sub-system is disposed on a second side of the processing sub-system, the first and second sides are opposing sides of the processing sub-system; and
wherein the processing sub-system comprises:
a delamination module for delaminating the first tape,
a wafer ring pick and place module for picking the wafer ring and placing the wafer ring on the WRM with the wafer,
a lamination module for laminating the second tape onto the wafer and wafer ring, and
the WRM for moving the wafer to the various processing modules of the processing sub-system along the WRM track, and wherein
a WRM home position of the WRM is situated centrally between the delamination and lamination modules proximate to the input sub-system, and
the wafer ring pick and place module is disposed adjacent to the home position and proximate to the output sub-system.

11. The system of claim 1 wherein:
the first wafer surface comprises a polished wafer surface;
the first tape comprises a backgrinding (BG) tape;
the second wafer surface comprises an active wafer surface; and
the second tape comprises a dicing tape.

12. A method of fabricating devices comprising:
providing a wafer to a lamination system having first and second major surfaces, wherein the first major surface includes a backgrinding tape (BG) tape laminated thereto;
picking up the wafer by a robotic module of an input sub-system of the lamination system;
aligning the wafer on the robotic module by a wafer aligner module;
transferring the wafer by the robotic module after wafer alignment to a wafer receiving module (WRM) of a processing sub-system of the lamination module;
placing the wafer on a positioning chuck on a WRM table of the WRM module by the robotic module, wherein the second major surface of the wafer is held by the positioning chuck;
transferring by the WRM with the wafer on the positioning chuck to various processing modules of the processing sub-system for delaminating the BG tape from the first wafer surface and for laminating a dicing tape onto the first wafer surface and a wafer ring, the wafer ring and wafer with the dicing tape laminated thereto to form a wafer ring assembly; and
transferring by the WRM with the wafer ring assembly to an output module of an output sub-system for outputting the wafer ring assembly for subsequent processing, including wafer singulation to separate the wafer into individual devices.

13. The method of claim 13 wherein delaminating the BG tape is performed by a delamination module of the processing sub-system, wherein delaminating the BG tape comprises:
curing the BG tape by a curing unit of the delamination module; and
peeling the cured BG tape off the first wafer surface by the delamination unit of the delamination module.

14. The method of claim 14 comprises aligning and placing a wafer ring onto the WRM table by a wafer ring pick and place module of the processing sub-system after delaminating the BG tape.

15. The method of claim 13 wherein laminating the dicing tape is performed by a lamination module, wherein laminating comprises:
cleaning the wafer after removal of the BG tape; and
laminating the dicing tape onto the first wafer surface and the wafer ring, the dicing tape is precut to size and is from a dicing tape roll.

16. The method of claim 13 comprises aligning and placing a wafer ring onto the WRM table by a wafer ring pick and place module of the processing sub-system after delaminating the BG tape.

17. The method of claim 13 wherein outputting the wafer ring assembly comprises:
transferring the WRM proximate to the output module;
picking the wafer ring assembly by an output robotic arm to transfer the wafer ring assembly to the output module.

18. The method of claim 18 wherein:
the output robotic arm is a component of a wafer ring pick and place module of the processing sub-system; and
the output robotic arm transfers the wafer ring assembly to an output conveyor of the output module to feed into a wafer ring assembly repository.

19. The method of claim 13 wherein transferring by the WRM comprises moving the WRM along a WRM track which is in processing communication with the various processing modules of the processing sub-system.

20. The method of claim 13 wherein:
picking up the wafer by the robotic module comprises picking the wafer with the second wafer surface facing upwards; and
flipping the wafer 180° such that the first wafer surface with the BG tape is facing upwards.
